(19) United States
(12) Patent Application Publication
(10) Pub. No.: US 2011/0313607 A1
(43) Pub. Date: Dec. 22, 2011

(54) SPEED CONTROL SYSTEM

(76) Inventors: Stanley J. Checketts, Providence, UT (US); Val Simmons, Providence, UT (US)

(21) Appl. No.: 13/165,164

(22) Filed: Jun. 21, 2011

Related U.S. Application Data
(60) Provisional application No. 61/357,364, filed on Jun. 22, 2010.

(51) Int. Cl. B60L 15/20; B60T 7/12; B23P 11/00; H05K 13/00

(52) U.S. Cl. 701/22; 29/592.1; 188/67; 29/428

(57) ABSTRACT

The present invention provides a speed control system, a speed control wheel mechanism and a spring compression system where magnetism is used as a unique speed reduction means to control excessive speed of a free rolling wheel, roller or pulley. The action takes place where a plurality of braking fins between two side plates are forced outward by the means of centrifugal force into one or more magnetic braking calipers. The braking fins are retained by the means of springs that are overcome by inertia of the centrifugal force with increasing speed. With the addition of the spring compression system using multiple springs of different compressive resistance over a wire rope or cable, a cushioning effect can be achieved over any given distance depending upon the speed and weight of the vehicle or device.

### FIELD OF THE INVENTION

This application provides a speed control system and speed control wheel mechanism for controlling the speed of any free-rolling equipment or mechanisms including, but not limited to, things such as zip-lines, roller coasters and sleds and a safety system to cushion the momentum when decelerating and coming to a stop.

### BACKGROUND OF THE INVENTION

Freely spinning tires, rollers and pulleys present a very definite problem in that there is no limit to the speed of rotation that they can achieve. In many cases the devices that incorporate these systems are required to travel down inclines where the uncontrolled acceleration is a desired effect as in roller coasters, zip-lines and sleds but without control of the maximum speed attained they may become very dangerous. In most cases, braking friction has been used as a means of speed control, but it imposes difficulties with heat and wears on the individual parts that require frequent inspection and replacement. Replacing worn cables on these activities can be very expensive. In the case of zip-lines, and other activities using a cable or rope, an additional cushioning is required to attain a completely safe and controlled stop. Freely rolling tires, rollers or pulleys incorporating speed control wheels and or spring compression systems can add a great deal of safety in many cases, even on devices that should not attain any appreciable speed but may break loose and get out of control.

Within the past decade, zip lines have become part of the “extreme sports” scene. One particular zip-line installed on a hill in the Costa Rican jungle has been given rave reviews. The Costa Rican system is really quite primitive, having a trolley with a single deep-groove nylon pulley riding on the suspended cable. In order to slow his descent, a rider must twist the trolley, thereby causing the flanges of the pulley to rub against the cable and generate friction. Kinetic energy is thus dissipated as heat. Riders who are particularly heavy may generate so much friction and related heat that the trolley pulley may fail prematurely. Such a system is potentially dangerous, as the riders themselves, must take responsibility for maintaining their descent speeds within a safe range, in order to avoid uncontrolled crashing into the lower cable support tower.

Numerous innovations for the speed control wheel and spring compression systems have been provided in the prior art that are described as follows. Even though these innovations may be suitable for the specific individual purposes to which they address, they differ from the present design as hereinafter contrasted. The following is a summary of those prior art patents most relevant to this application at hand; as well as a description outlining the difference between the features of the speed control wheel mechanism and spring compression system prior art.

US Patent Application Publication No. US 2002/0162477 A1 of Emiliano Palumbo describes a high-speed dual cable zip line ride whereby the participant(s) ascends by a mechanical motor drive system and descend using a combination of mechanical and gravitational forces. The participant(s) will be secured in either a harnessed or a seated tram configuration. The control of the deceleration and stopping of the ride will be performed by one of four mechanical configurations depending on the dimension of the ride (i.e. Length and height of the ride). These configurations will be an air shock system, a nitrogen shock system, a hydraulic disc braking system, or a magnetic disc braking system. In all embodiments of the ride, appropriate platforms and procedures for safely embarking and disembarking will be utilized.

This patent describes a high-speed dual cable zip line ride that uses an air shock system, a nitrogen shock system, a hydraulic disc braking system, or a magnetic disc braking system to stop, but does not control the speed of the vehicle as does the speed control wheel until the actual braking process is required. It does not employ the unique cushioned mechanism of the spring compression system.

U.S. Pat. No. 6,666,773 of Michael Troy Richardson tells of a zip-line thrill ride system that includes a cable suspended between an upper cable support tower and platform which, together, function as the harnessing, loading, and take-off point for the ride, and a lower cable support tower and platform which together, function as the landing, unloading and unharnessing point of the ride. Multiple, substantially identical trolleys are designed to quickly engage and disengage the cable. The trolley includes a frame of generally I-beam cross section, a generally tubular brake retainer, having a longitudinal slit therein, is welded to an upper rear portion of the frame. A grooved, generally cylindrical brake fabricated from a durable polymeric material is rotatably affixed within the tubular brake retainer. When the trolley is affixed to the suspended cable by sliding the cable into the slit and rotating the brake, the grooved insert rides against the suspended cable and generates friction.

This patent tells of a zip-line thrill ride system that includes a cable suspended between an upper cable support tower and platform. It does not employ a means for controlling the overall speed of the ride. It does not describe the unique attributes of the speed control wheel mechanism that can be used on a variety of other different applications.

US Patent Application Publication No. US 2006/0288901 A1 of Eric Scott Cylvic relates to a recreational ride that employs a suspended tensioned static cable that allows the user to gravitationally ride, harnessed to a rolling trolley attached to the cable, from an upper platform to a lower platform. The trolley includes a brake assembly that is attached to a brake arm through a bolted connection, which greatly reduces the cost and complexity of the brake assembly and reduces the chances of operator error when mounting the trolley on the cable. The brake assembly includes two adjacent, separate, aligned brake pads fabricated of different materials, a forward pad being a non-metallic material and a rearward pad being a metallic material. A wheel assembly portion of the trolley includes a sheave plate, bolted to a brake arm that is permitted to pivot about its point of attachment to the brake arm to thereby eliminate fatigue forces on the wheel assembly.

This patent relates to a recreational ride that employs a suspended tensioned static cable that allows the user to gravitationally ride, harnessed to a rolling trolley attached to the cable that uses a braking system but does not control the overall speed of the ride.

U.S. Pat. No. 7,381,137 of Robert L. Steele et al. describes a braking and motion-arrest apparatus for braking the arrival of a zip line cable rider at a landing platform and arresting the rider's motion to retain the rider at the platform. A frame is mounted on the cable to allow longitudinal rolling movement of the frame along the cable. A self-closing one-way latch is provided at the forward end of the frame. The latch includes a pair of capture plates which are normally inwardly biased toward one another, on opposite sides of the cable. The rider is tethered to a pulley block which rolls along the cable and collides with the latch. The collision force drives the plates laterally away from the cable, allowing the pulley block to roll through the latch. After the pulley block rolls past the latch, the plates' normal biasing closes the latch, preventing the pulley block from rolling back through the latch.

This patent describes a braking and motion-arrest apparatus for braking the arrival of a zip line cable rider at a landing platform and arresting the rider's motion to retain the rider at the platform but also does not control the overall speed of the ride.

None of these previous efforts, however, provides the benefits attendant with the present speed control system and speed control wheel mechanism and spring compression system and could not be adapted to working on freely rolling tires, rollers or pulleys. The present design achieves its intended purposes, objects and advantages over the prior art devices through a new, useful and unobvious combination of method steps and component elements, with the use of a minimum number of functioning parts, at a reasonable cost to manufacture, and by employing readily available materials.

In this respect, before explaining at least one embodiment of the speed control system and speed control wheel mechanism and spring compression system in detail it is to be understood that the design is not limited in its application to the details of construction and to the arrangement, of the components set forth in the following description or illustrated in the drawings. The speed control system and speed control wheel mechanism and spring compression system are all capable of other embodiments and of being practiced and carried out in various ways. In addition, it is to be understood that the phraseology and terminology employed herein are for the purpose of description and should not be regarded as limiting. As such, those skilled in the art will appreciate that the conception, upon which this disclosure is based, may readily be utilized as a basis for designing of other structures, methods and systems for carrying out the several purposes of the present design. It is important, therefore, that the claims be regarded as including such equivalent construction insofar as they do not depart from the spirit and scope of the present application.

### SUMMARY OF THE INVENTION

The principal advantage of the speed control system and speed control wheel mechanism and spring compression system is to control the speed and bring to a controlled stop any vehicle or device using an otherwise uncontrolled freely rolling system.

Another advantage of the speed control system and speed control wheel mechanism and spring compression system is the unique method of using magnetism as a means of maintaining a given maximum speed, eliminating the heat and friction caused by conventional braking processes.

Another advantage of the speed control system and speed control wheel mechanism and spring compression system is the elimination of the wear and damage caused by conventional braking systems where with the magnetic braking system there is no contact between any of the wheel components.

Another advantage of the speed control system and speed control wheel mechanism and spring compression system is the increasing speed of the wheel causes centrifugal force to stretch the springs holding the braking fins so that they will slowly extend into the magnetic calipers causing and maintaining a desired reduction of the speed.

Another advantage of the speed control system and speed control wheel mechanism and spring compression system is by using a plurality of braking fins around the speed control wheel an even speed control pressure is maintained.

Another advantage of the speed control system and speed control wheel mechanism and spring compression system is that the maximum speed can be set by the means of using different tension springs on the braking fins.

Another advantage of the speed control system and speed control wheel mechanism and spring compression system is that it can be incorporated as an integral part of a variety of devices such as wheels, rollers or pulleys.

Another advantage of the speed control system and speed control wheel mechanism and spring compression system is that one or more magnetic calipers can be used around the wheel, thus increasing or decreasing the braking force.

Another advantage of the speed control system and speed control wheel mechanism and spring compression system is that a device or vehicle on a Zip-Line can be brought to a controlled and cushioned stop.

An advantage of the speed control system and speed control wheel mechanism and spring compression system and more particularly with the spring compression system, is by using multiple springs of different compressive resistance a progressive cushioning effect can be achieved over any given distance depending upon the speed and weight of the vehicle or device.

Yet another advantage of using the combination of the speed control system and speed control wheel mechanism and spring compression system is the number of mechanisms used on Zip-Lines, Roller Coasters and Sleds along with many other mechanical devices can be greatly reduced.

These together with other advantages of the speed control system and speed control wheel mechanism and spring compression system, along with the various features of novelty, which characterize the design, are pointed out with particularity in the claims annexed to and forming a part of this disclosure. For a better understanding of the speed control system and speed control wheel mechanism and spring compression system, its operating advantages and the specific objects attained by its uses, reference should be made to the accompanying drawings and descriptive matter in which there are illustrated preferred embodiments of the speed control system and speed control wheel mechanism and spring compression system. There has thus been outlined, rather broadly, the more important features of the design in order that the detailed description thereof that follows may be better understood, and in order that the present contribution to the art may be better appreciated. There are additional features of the speed control system and speed control wheel mechanism and spring compression system that will be described hereinafter and which will form the subject matter of the claims appended hereto.

The speed control system and speed control wheel mechanism and spring compression system consists in part of a speed control wheel mechanism having two side plates separated by the means of a central spacer on an arbor having a shoulder at one end and a tubular section that extends through the orifices in the two side plates. A securing means such as a locking collar or a threaded nut will hold the side plates evenly spaced apart. The two side plates and central spacer are keyed to the arbor by the means of a conventional keyway to prevent the separate rotation of the side plates. A plurality of braking fins are evenly spaced between the two side plates with a liner guiding means such as two bearings or bushings on both sides that travel within a guide slots in the two side plates to guide the braking fins emanating out from the center of the wheel. The guide slots are evenly spaced around the wheel. Each of the braking fins is restrained by the means of two or more springs attached in orifices on braking fins and to pins in the central area between the side plates that hold the braking fins into the center of the speed control wheel. One or more magnetic braking calipers are held in a close proximity to the braking fins around the wheel by a supporting structure. As the speed of the speed control wheel increases centrifugal force exerts pressure on the springs to extend the braking fins into the cavity of the magnetic braking calipers. Springs with different tension can be used to achieve a desired maximum speed to be maintained. An increased degree of drag is put on the braking fins as they enter further into the braking calipers. The braking fins must be made of a non-ferrous alloy.

The speed control system and speed control wheel mechanism and spring compression system will have the added benefit of a spring compression system where a controlled stopping mechanism is desired. The spring compression system will consist of one or more polymer spring guides over a wire rope with one or more springs of different compressive spring rates. The polymer spring guides will consist of a central section with sections at either end of a reduced diameter. An orifice running through the center of the polymer spring guide will be large enough for the wire rope to pass freely. The outer diameter of the end sections of the polymer spring guides will easily fit within the inner diameter of the springs. The polymer spring guides will guide the springs along the wire rope and prevent the springs from bucking or coming into contact with the wire rope. As the springs compress, the separate spring guides come together, the end sections of the guides come into contact preventing the springs from over compression. By using springs of increasing compressive rates an even cushioning is achieved. An example of this would be spring compressive rates of 300 lbs, 360 lbs, 450 lbs, 650 lbs, 800 lbs, and 1500 lbs. This application includes any combination of springs combined to achieve an optimum g-force of approximately 1.0 to 2.5. In addition, it includes the unique side-by-side vehicle that allows riders to decelerate from a variety of speeds into the spring compression system without swinging up into the wire rope.

Additionally, the spring compression system may employ optional compression stops between the spring guides which limit the amount of compression of the springs. These guides are cylindrical in shape and are of varying length depending upon the diameter and size of the spring. These compression stops slide easily over the cable and are smaller in outside diameter than the inside diameter of the spring.

With respect to the above description then, it is to be realized that the optimum dimensional relationships for the parts of this application, to include variations in size, materials, shape, form, function and manner of operation, assembly and use, are deemed readily apparent and obvious to one skilled in the art. All equivalent relationships to those illustrated in the drawings and described in the specification intend to be encompassed by the present disclosure. Therefore, the foregoing is considered as illustrative only of the principles of the speed control system and speed control wheel mechanism and spring compression system. Further, since numerous modifications and changes will readily occur to those skilled in the art, it is not desired to limit the design to the exact construction and operation shown and described, and accordingly, all suitable modifications and equivalents may be resorted to, falling within the scope of this application.

### BRIEF DESCRIPTION OF THE DRAWINGS

The accompanying drawings, which are incorporated in and form a part of this specification, illustrate various embodiments of the speed control system and speed control wheel mechanism and spring compression system and together with the description, serve to explain the principles of this application.

FIG. 1 depicts a perspective view of one embodiment of the speed control wheel, constructed in accordance with the present invention.

FIG. 2 depicts an exploded perspective view of the speed control wheel, constructed in accordance with the present invention.

FIG. 3 depicts a front view of an alternate embodiment of the speed control wheel attached to a pulley wheel, constructed in accordance with the present invention.

FIG. 4 depicts a side view of an alternate embodiment of the speed control wheel attached to a pulley wheel, constructed in accordance with the present invention.

FIG. 5 depicts an exploded perspective view of the spring compression system, constructed in accordance with the present invention

FIG. 6A depicts a perspective view of the spring compression system, constructed in accordance with the present invention.

FIG. 6B depicts a perspective view of the spring compression system, illustrating the optional compression stops, constructed in accordance with the present invention.

FIG. 7 depicts a side elevation view of a zip-line construction, incorporating the speed control system, speed control wheel mechanism and the spring compression system, constructed in accordance with the present invention.

FIG. 8 depicts a front view of the motor and drive shaft assembly, including the speed control wheel, drive wheel and friction brake, constructed in accordance with the present invention.

FIG. 9 depicts a front view of a preferred embodiment of the speed control system illustrating the motor and drive shaft assembly, including the speed control wheel, drive wheel and friction brake, constructed in accordance with the present invention.

FIG. 10 depicts a front view of an alternate embodiment of the speed control wheel mechanism, constructed in accordance with the present invention.

FIGS. 11A and 11B depict a side view of an alternate embodiment of the speed control wheel mechanism, constructed in accordance with the present invention.

FIG. 12 depicts a front view of an alternate embodiment of the speed control system illustrating the motor and drive shaft assembly, including the encoder, drive wheel and disc brake, constructed in accordance with the present invention.

FIGS. 13A, 13B and 13C depict a top and side view of the electronic latch system, constructed in accordance with the present invention.

For a fuller understanding of the nature and advantages of the Speed Control Wheel and Spring Compression System, reference should be had to the following detailed description taken in conjunction with the accompanying drawings which are incorporated in and form a part of this specification, illustrate embodiments of the design and together with the description, serve to explain the principles of this application.

### DETAILED DESCRIPTION OF THE PREFERRED EMBODIMENTS

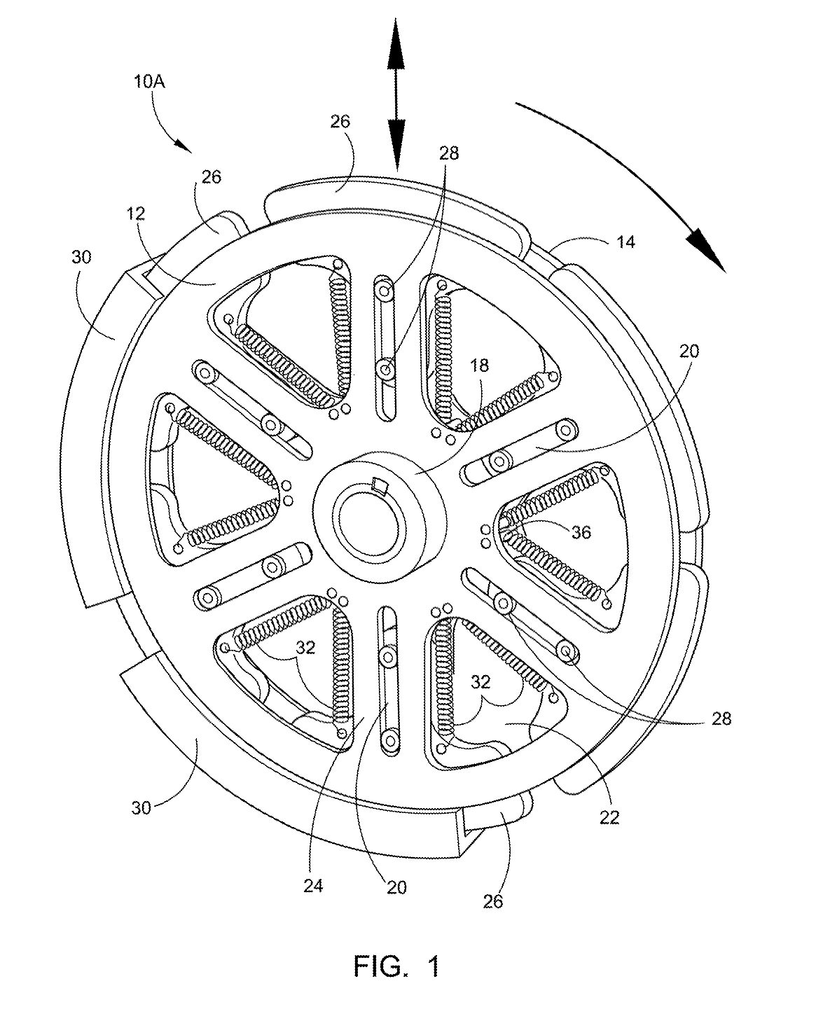

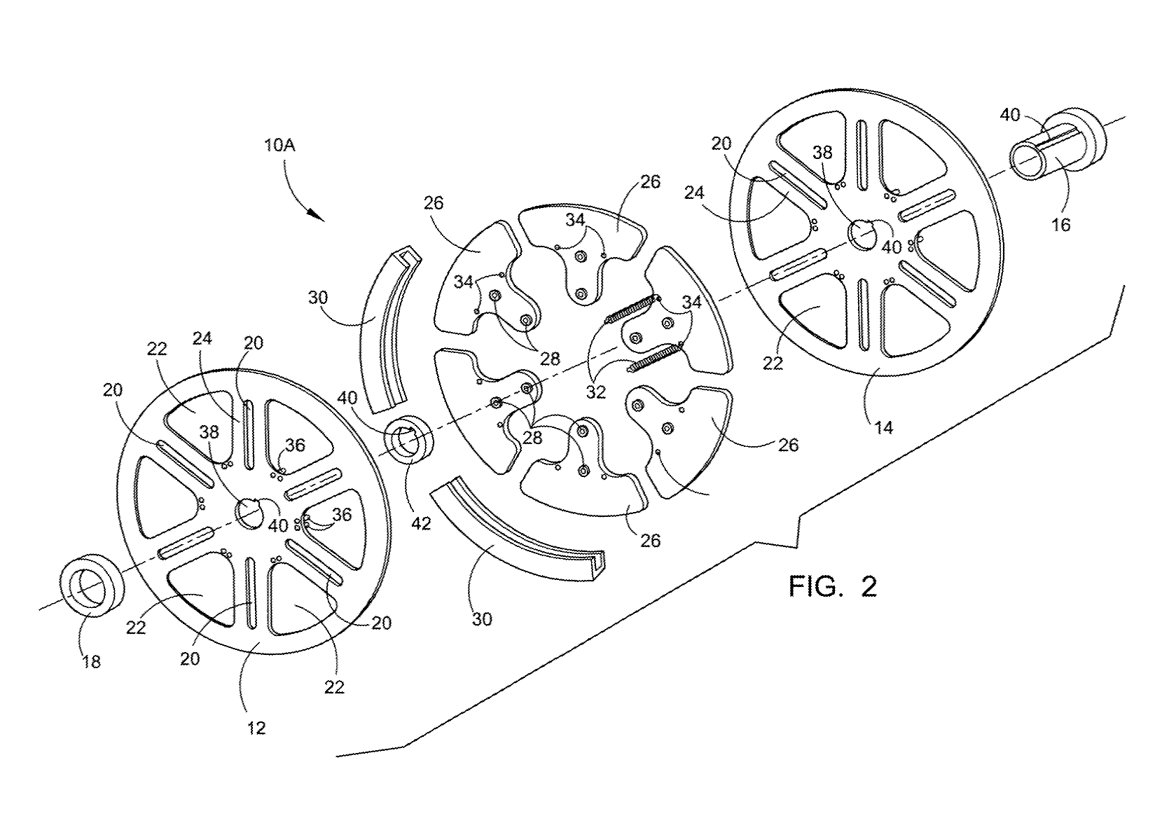

Referring now to the drawings, wherein similar parts of the Speed Control Wheel 10A and 10B are identified by like reference numerals, there is seen in FIG. 1 a perspective view of the Speed Control Wheel 10A. This view illustrates two typical side plates 12 and 14 being supported by the means of a central arbor 16 (as shown in FIG. 2 only) and a locking collar 18. The two side plates 12 and 14 have a plurality of guide slots 20 emanating out from the center. Openings 22 are used to lighten the weight of the side plates 12 and 14 and create the effect of spokes 24 on a wheel. A plurality of braking fins 26 translate up and down between the two side plates 12 and 14 by the means of two bearings or bushings 28 on both sides of each braking fin 26 that are held within the guide slots 20. The braking fins 26 must be made of a non-ferrous alloy. Each of the braking fins 26 is restrained by the means of two springs 32 attached to orifices 34 or pins in the braking fin 26 and to spring attachment pins 36 in the central area between the side plates 12 and 14 holding the braking fins 26 into the center of the Speed Control Wheel 10A.

One or more magnetic braking calipers 30 are held in a close proximity to the braking fins 26 around the wheel by a supporting structure. The braking fins 26 are shown in the extended position with the springs 32 stretched out illustrating the wheel exceeding the desired speed. This view shows the braking fins 26 in the extreme position within magnetic braking calipers 30 where the greatest braking effect will be attained. The desired effect of the braking process is that it will start as the braking fins 26 approach the magnetic braking calipers 30 and a gentle reduction of speed is attained. This system has not been designed for a sudden stop but just for maintaining a given maximum speed.

FIG. 2 depicts an exploded perspective view of the Speed Control Wheel 10A further illustrating the two typical side plates 12 and 14 with the guide slots 20, openings 22 and a central orifice 38 with a keyway 40. The side plates 12 and 14 are held apart by the means of the spacer 42, which has a matching keyway 40. The central arbor 16 has a shoulder 44 that is against the side plate 14 extending through the spacer 42 and then through the side plate 12 to be held tightly in place by the means of the locking collar 18. There is a matching keyway 40 on the central arbor 16 to secure the positions of the parts in alignment when a key is inserted into the keyway 40. The central arbor 16 will be secured to the axle of a freely rotating tire, roller and pulley to maintain a maximum speed control.

FIG. 3 depicts a front view of an alternate embodiment of the Speed Control Wheel 10B having been permanently attached to a pulley wheel 50. The basic components will be the same with two typical side plates 12 and 14 being supported by the means of a central arbor 16 that is integral part of the pulley wheel 50. The two side plates 12 and 14 have a plurality of guide slots 20 emanating out from the center. Optional openings 22 are used to lighten the weight of the side plates 12 and 14 and create the effect of spokes 24 on a wheel. A plurality of braking fins 26 translate up and down between the two side plates 12 and 14 by the means of two bearings or bushings 28 on both sides of each braking fin 26 that are held within the guide slots 20. The braking fins 26 must be made of a non-ferrous alloy that will not be attracted by the magnetic braking calipers 30 but the rest of the components of the device will be made any non-ferrous material such as aluminum and not be affected by the magnetism. Each of the braking fins 26 is restrained by the means of one or more springs 32 attached to orifices 34 in the braking fin 26 and to spring attachment pins 36 in the central area between the side plates 12 and 14 holding the braking fins 26 into the center of the Speed Control Wheel 10B. One or more magnetic braking calipers 30 are held in a close proximity to the braking fins 26 around the wheel by a supporting structure. The braking fins 26 are shown again in the extended position with the springs 32 stretched out illustrating the wheel exceeding the desired speed. This view additionally shows the braking fins 26 in the extreme position within magnetic braking calipers 30 where the greatest braking effect will be attained.

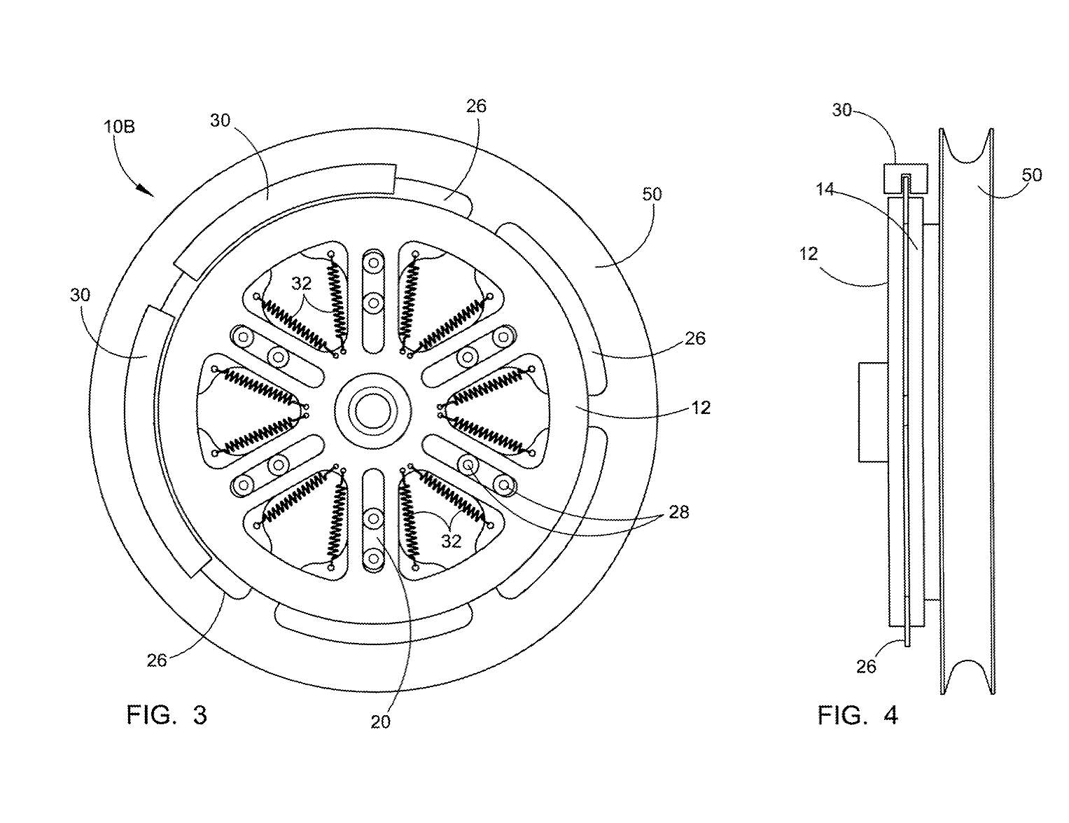

FIG. 4 depicts a side view of an alternate embodiment of the Speed Control Wheel 10B attached to a pulley wheel 50. It must be understood that the Speed Control Wheel 10B can be permanently attached or removable from a variety of different tires, rollers, pulleys and or drive shafts still remain within the scope of this application.

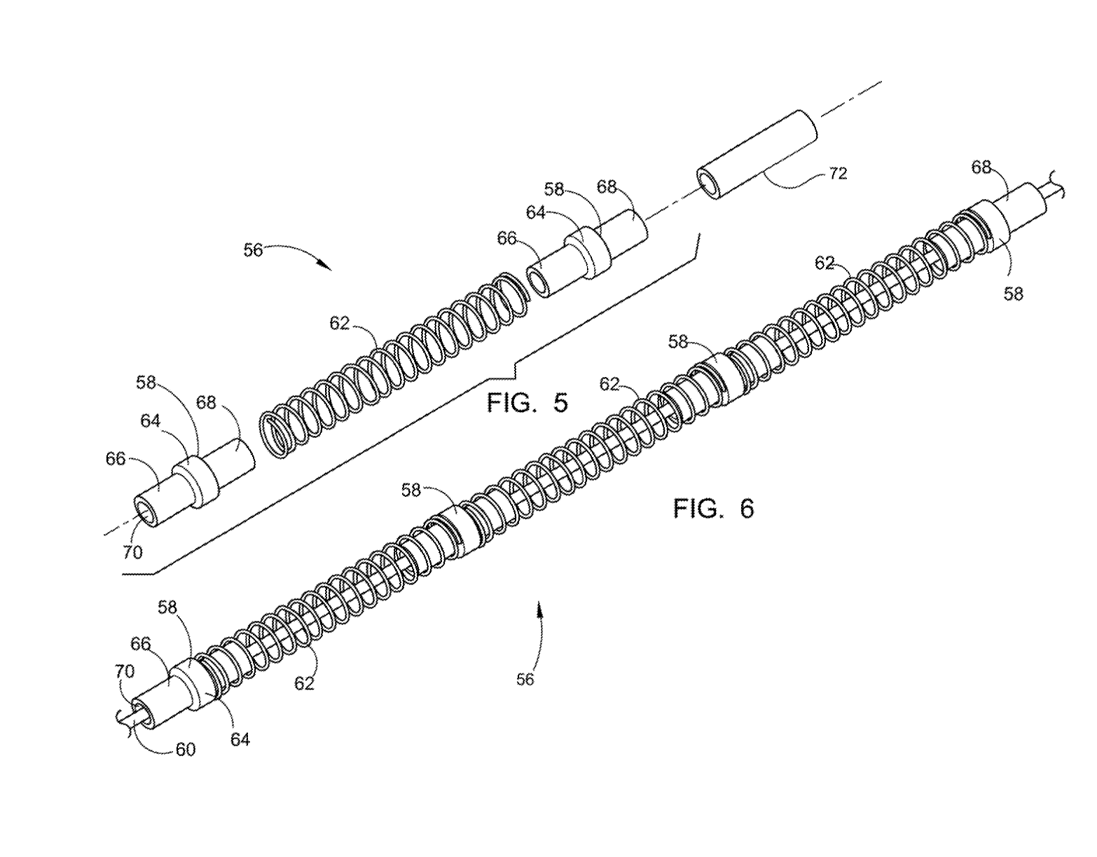

FIG. 5 depicts an exploded perspective view of the Spring Compression System 56 consisting of one or more polymer spring guides 58 over a wire rope 60 with one or more springs 62 of different compressive spring rates. The polymer spring guides 58 will consist of a central section 64 with sections at either end 66 and 68, of a reduced diameter. An orifice 70 running through the center of the polymer spring guide 58 will be large enough for the wire rope 60 to pass freely. The outer diameter of the end sections 66 and 68 of the polymer spring guides 58 will be easily fit within the inner diameter of the springs 62. This allows the springs to compress and slide onto the spring guides.

FIG. 6 depicts a perspective view of an assembled Spring Compression System 56 showing a series of spring guides 58 and springs 62 in place over the wire rope 60. As illustrated in FIG. 6B, the spring compression system 56 may employ optional compression stops 72 (as shown in FIG. 5 only) between the spring guides 58 which limit the amount of compression of the springs 62. These guides are cylindrical in shape and are of varying length depending upon the diameter and size of the spring 62. These compression stops slide easily over the wire rope or cable 60 and are smaller in outside diameter than the inside diameter of the spring 62. They can be made from softer compressible materials such as rubber, or rigid materials such as thermoplastics or metals. They act to reduce over-stressing of the springs.

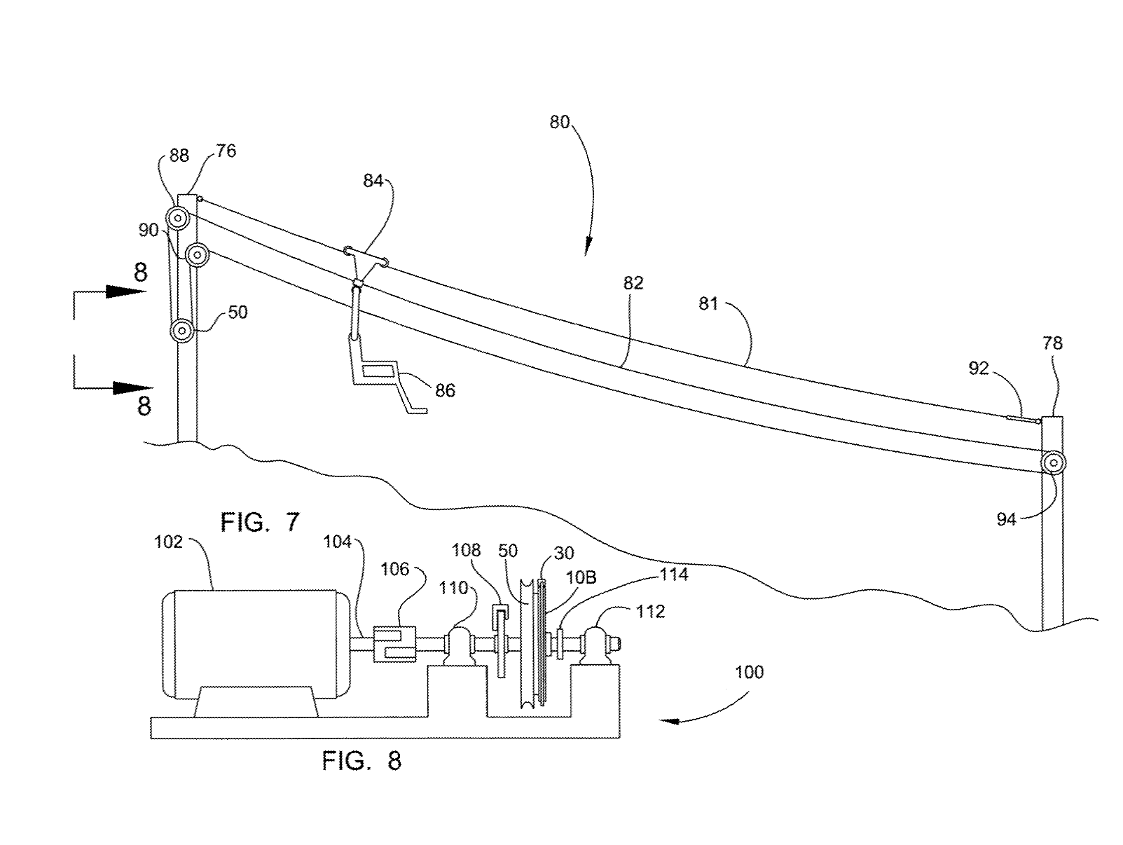

FIG. 7 depicts a side elevation view of a zip line construction 80, incorporating the Speed Control Wheel and the Spring Compression System. The zip line construction 80 comprises a stationary support cable 81 and a continuous free-wheeling cable 82 extending between two supports 76 and 78. A cable-to-chair mount 84 connects the stationary support cable 81 and the free-wheeling cable 82 to a suspended cart or chair 86. The cart or chair 86 is movably attached to the stationary support cable 81 and through the action of wheels in the mount 84 is free to roll down the stationary cable 81. The chair is fixed to the free-wheeling cable 82, and moves with that cable as it is actuated by the drive motor (see FIG. 8). The free-wheeling cable 82 runs through pulley wheel 50, and cable guide wheels 88 and 90 on the proximal support 76, and through cable guide wheel 94 on distal support 78. The stationary cable 81 is directly attached to proximal support 76 and distal support 78, and may have one or more braking springs 92 at the distal attachment point, where the stationary cable attaches to the distal support 76. The free-wheeling cable is actuated by the drive motor (see FIG. 8) through pulley wheel 50.

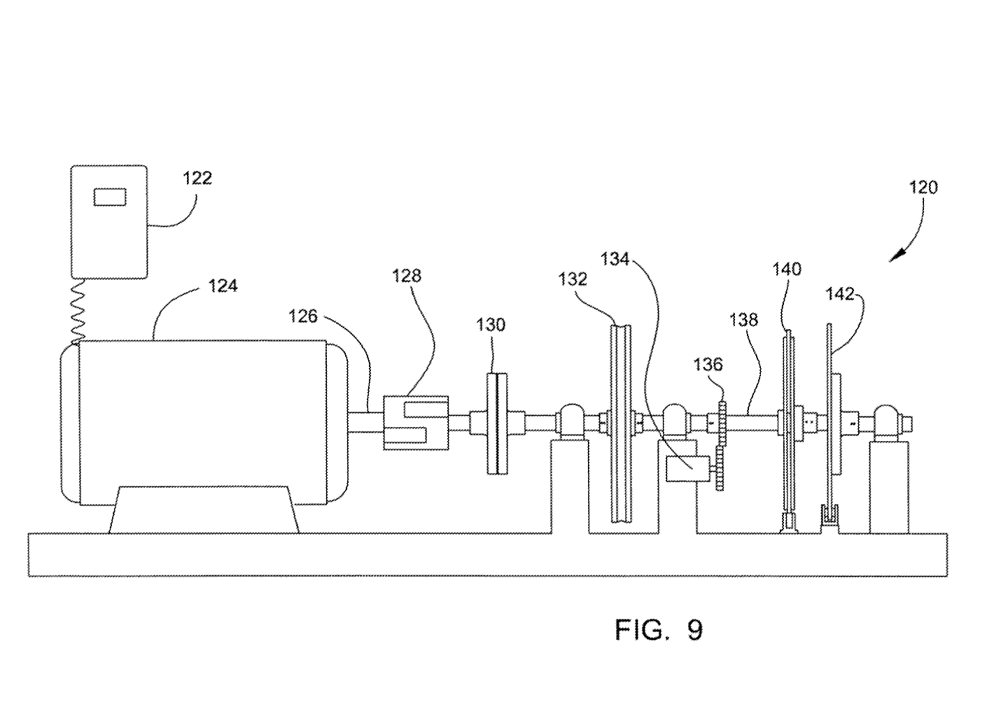

FIG. 8 depicts a front view of the motor and drive shaft assembly 100, including the Speed Control Wheel 10B, pulley/drive wheel 50 and friction brake 108. The drive motor 102 rotates a drive shaft 104 and through a coupler 106, rotational energy is transferred to the rest of the assembly, including drive/pulley 50 to actuate the zip line. Along the drive shaft are mounted the friction brake 108, drive/pulley 50 and the Speed Control Wheel 10B, as well as bearings 110 and 112. Magnetic braking calipers 30 act as a control mechanism for the speed control wheel 10B, as previously described. The friction brake 108 acts to lock the chair in the loading area for safe loading and unloading of the cart or chair 86. An encoder 114 allows for computer control of the speed by communicating with a computer's CPU (not shown) used for controlling the drive motor through a variable frequency drive (VFD) unit (see FIG. 9 below for more detail).

FIG. 9 depicts the preferred embodiment of the invention with respect to the illustrated speed control system 120 employing the speed control wheel 140. The preferred embodiment utilizes the centrifugally operated speed control wheel 140 in conjunction with the VFD 122, drive motor 124, coupler or gear reduction box 128, clutch or pulley assembly 130 for disengagement, drive shaft 126, drive wheel 132, encoder 134 and encoder gear assembly 136, disc brake assembly 142 and support bearings 138 along with the cables, pulleys, cart towers or supports, and compression spring assembly (all as shown in FIG. 7) as previously illustrated and described. The clutch or pulley assembly 130 is used to disengage the drive motor to allow free-wheeling of the cart or chair 86. The encoder 134 and encoder gear assembly 136 determines the position of the cart or chair 86 for release, return and secure latching.

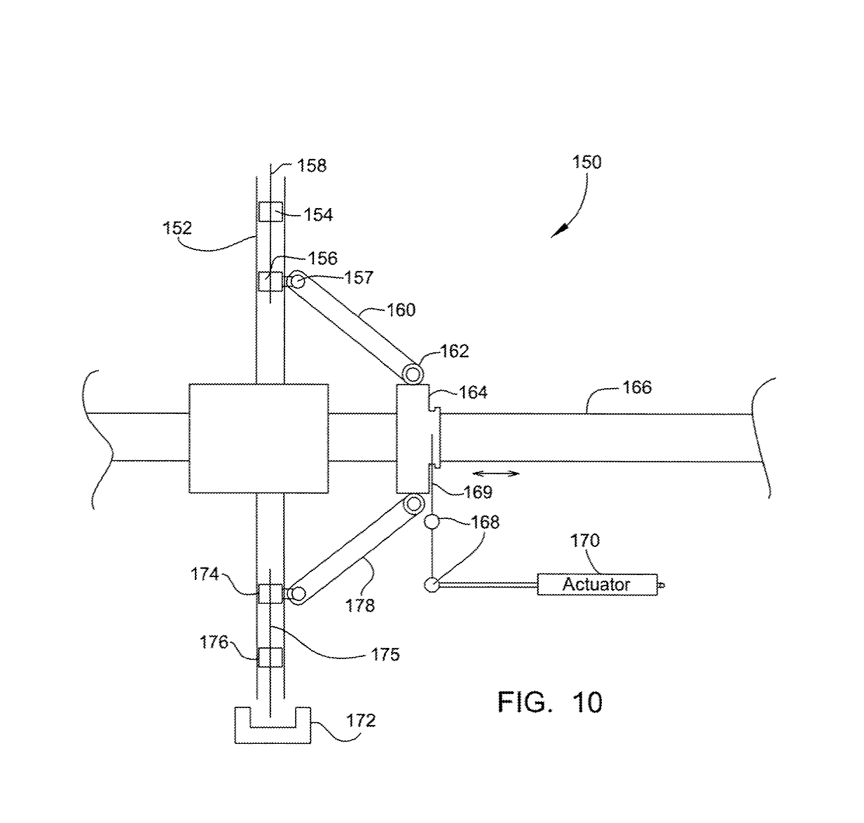

FIG. 10 depicts an alternative embodiment of the speed control wheel 150 which utilizes mechanical arms 160 and 178 to move fins 158 and 175 in and out with an electronic actuator 170. This system is operated in conjunction with the VFD and the encoder as described in FIG. 9 above, with the exception of using a mechanically operated speed control wheel to engage and disengage the fins. In operation, the actuator 170 acts to move the thrust bearing 164 through lever 169 having pivots 168. When the thrust bearing moves along drive shaft 166, arms 160 and 178 are pulled or pushed and pivot on pivot points 157 and 162 on arm 160 (pivot points not referenced on arm 178). Each fin 158 and 175 are housed within the outer plate 152 and include two bearings 154 and 156 on fin 158, and bearings 174 and 176 on fin 175. Bearing 156 on fin 158 is pivotally attached to arm 160 through pivot point 157, and similarly bearing 174 on fin 175 is pivotally attached to arm 178. When the thrust bearing 174 moves toward this speed control wheel system 150, the fins are actuated outward and are exposed to magnetic brake 172 thereby slowing the speed of wheel rotation and resulting in braking (slowing down of) the zip-line.

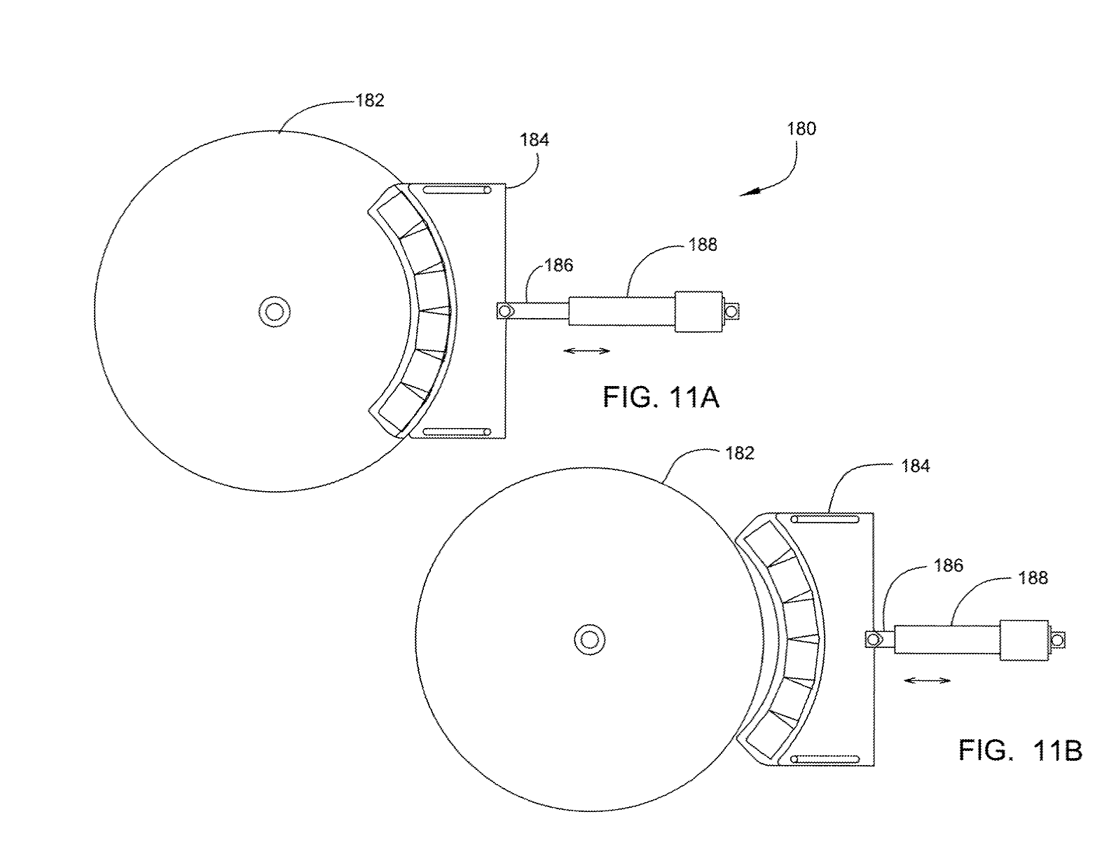

FIGS. 11A and 11B illustrate an alternative speed control wheel construction 180 in the engaged FIG. 11A and disengaged FIG. 11B positions. Here, the speed control wheel system 180 includes a solid non-ferrous or aluminum disc 182 and a mechanically moving magnetic brake assembly 184 mounted on shaft 186. Actuator 188 acts to move the magnetic brake assembly toward or away from the disc 182 thereby slowing it when engaged as shown in FIG. 11A, and allowing acceleration or free-wheeling when disengaged as shown in FIG. 11B.

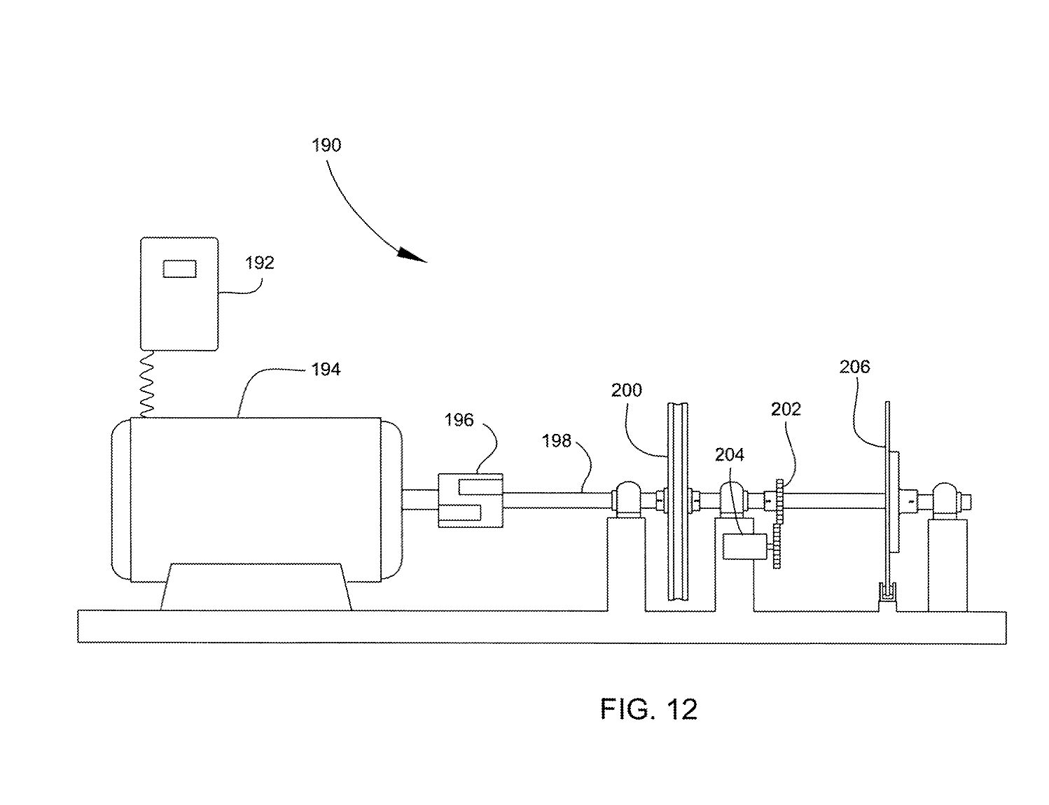

FIG. 12 illustrates another alternate speed control system 190 utilizing the drive motor 194 in communication with a VFD 192 alone as the speed control mechanism. There is no speed control wheel or magnetic brake assembly present in this embodiment. Additionally, there is no clutch or pulley assembly for engagement or disengagement. The drive motor 194 is coupled directly to the drive shaft 198 through a gear reduction box 196. The rate of decent and return of the zip-line connected to the drive wheel 200 is controlled by the drive motor thought the use of the encoder 204 and encoder gear assembly 202 as well as disc brake 206. As with other variations, the VFD 192 controls the speed of the drive motor. In all variations, a computer program controls all aspects of the different operations and mechanisms including sensing when the cart has stopped moving in its decent at which time the compression springs are compressed, and a return signal engages the return sequence.

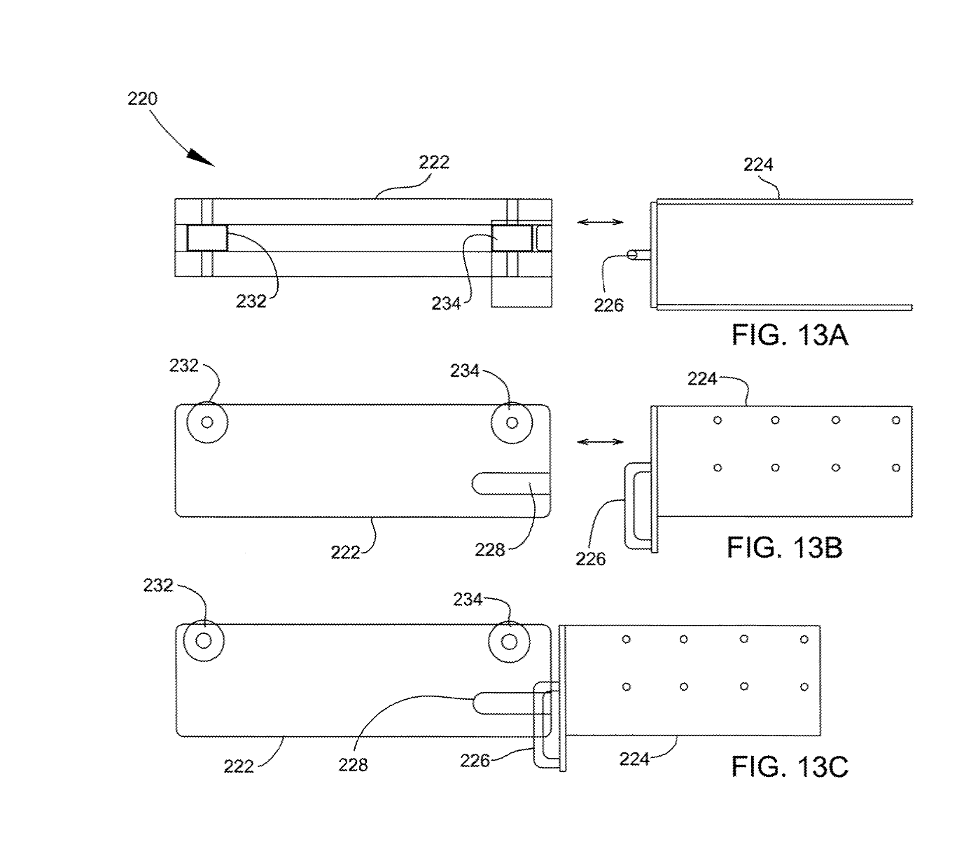

FIGS. 13A, 13B and 13C depict the electronic latch system 220 used for securing the cart in a fixed position. FIG. 13A illustrates a top view of the disengaged electronic latch system 220 having an opposing latch accepting unit 222 including wheel rollers 232 and 234, and a latch tab housing 224 having latch tab 226. FIG. 13B shows a side view of the electronic latch system 220 also in the disengaged position. FIG. 13C shows a side elevation view of the electronic latch system 220 in the engaged position illustrating the latch tab 226 locked to the latch accepting unit 222 in latching slot 228. At the top of the zip-line return sequence at the desired location of the cart, the cart automatically engages this latch mechanism thus securing the cart in a fixed position, for safe loading and unloading of passengers. When the cart latches, a signal is sent to turn off the drive motor, disengage the drive shaft, and engage the disc brake. Even though the cart is securely latched and tethered to the upper tower assembly, the disc brake is applied as a back-up, further securing the cart by means of the drive wheel and cable assembly. Thus, the hydraulic disc brake is a back-up securing mechanism for safety purposes.

Finally, it should be understood that the entire speed control system can be run from top to bottom, or alternatively, from bottom to top. Loading of passengers can be done either at the apex of the zip-line, to transport them down to the bottom, or it can be used to pick up passengers at the bottom and transport them to the top of the zip-line. Thus, loading of passengers can be accomplished either at the top or bottom of the zip-line. Moreover, electronic sensors tell the computer control CPU the location and speed of the cart at all times and these electronic sensors are also employed to send signals to securely latch the cart, keeping it from moving down the zip-line, or open the latch freeing it for movement up or down the zip-line.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

We claim:

1. A speed control system comprising:
a) a computer controlled variable frequency drive, a drive motor and a drive shaft;
b) a coupler or gear reduction box, a clutch or pulley assembly, an encoder and an encoder gear assembly;
c) a speed control wheel having braking fins and one or more magnetic braking caliper assemblies; and
d) a disc brake assembly;
whereby said computer controls said variable frequency drive which controls said drive motor, and in conjunction with the braking action of said speed control wheel having braking fins and one or more magnetic braking calipers, thereby controls the overall speed of the system.

2. The speed control system, according to claim 1, wherein said speed control wheel having braking fins and one or more magnetic braking caliper assemblies further includes braking fins which are attached to said speed control wheel with one or more springs, and said braking fins are thereby radially movable outward as the rotation of the speed control wheel increases.

3. The speed control system, according to claim 2, wherein said radial movement of said braking fins outward forces the surface area of said braking fins to increase within said magnetic calipers, and thereby causes a slowing in the rotation of said speed control wheel through magnetic attraction of the braking fin to the magnetic caliper.

4. The speed control system, according to claim 2, wherein six of said radially movable braking fins are used, each being attached to the speed control wheel using two springs.

5. The speed control system, according to claim 3, wherein said pulley assembly includes a pulley wheel and said speed control wheel is fixed to said pulley wheel to control the speed of the wire rope movement driven by said pulley wheel.

6. A method for making a speed control system, comprising the steps of:
a) providing a computer controlled variable frequency drive, a drive motor and a drive shaft;
b) providing a coupler or gear reduction box, a clutch or pulley assembly, an encoder and an encoder gear assembly;
c) providing a speed control wheel having braking fins and one or more magnetic braking caliper assemblies; and
d) providing a disc brake assembly;
whereby said computer controls said variable frequency drive which controls said drive motor, and in conjunction with the braking action of said speed control wheel having braking fins and one or more magnetic braking calipers, thereby controls the overall speed of the system.

7. The method of making a speed control system, according to claim 6, wherein said speed control wheel having braking fins and one or more magnetic braking caliper assemblies further includes braking fins which are attached to said speed control wheel with one or more springs, and said braking fins are thereby radially movable outward as the rotation of the speed control wheel increases.

8. The method of making a speed control system, according to claim 7, wherein said radial movement of said braking fins outward forces the surface area of said braking fins to increase within said magnetic calipers, and thereby causes a slowing in the rotation of said speed control wheel through magnetic attraction of the braking fin to the magnetic caliper.

9. The method of making a speed control system, according to claim 7, wherein six of said radially movable braking fins are used, each being attached to the speed control wheel using two springs.

10. The method of making a speed control system, according to claim 8, wherein said pulley assembly includes a pulley wheel and said speed control wheel is fixed to said pulley wheel to control the speed of the wire rope movement driven by said pulley wheel.

11. A speed control wheel mechanism comprising:
a) a pair of outer plates rotationally attachable to a drive shaft and having slots therein;
b) one or more braking fins movably held between said outer plates having one or more bushings within said slots and anchored to said outer plates by one or more springs; and
c) one or more magnetic braking calipers located around the periphery of said outer plates;
whereby when said outer plates spin about a drive shaft, the centrifugal force causes said braking fins to move outward away from said drive shaft and toward and into said magnetic braking calipers thereby causing slowing of the spinning through the magnetic attraction of said braking fins and said magnetic braking calipers.

12. The speed control wheel mechanism, according to claim 11, wherein the speed control wheel mechanism is incorporated into a zip line amusement ride to control the speed of the free-wheeling cable.

13. A method for making a speed control wheel mechanism, comprising the steps of:
a) providing a pair of outer plates rotationally attachable to a drive shaft and having slots therein;
b) providing one or more braking fins movably held between said outer plates having one or more bushings within said slots and anchored to said outer plates by one or more springs; and
c) providing one or more magnetic braking calipers located around the periphery of said outer plates;
whereby when said outer plates spin about a drive shaft, the centrifugal force causes said braking fins to move outward away from said drive shaft and toward and into said magnetic braking calipers thereby causing slowing of the spinning through the magnetic attraction of said braking fins and said magnetic braking calipers.

14. The method of making a speed control wheel mechanism, according to claim 13, wherein the speed control wheel mechanism is incorporated into a zip line amusement ride to control the speed of the free-wheeling cable.

15. A spring compression braking system, comprising:
a) one or more spring guides; and
b) one or more compression springs;
c) an arrangement of a series of one or more alternating spring guides and compression springs along a cable; and
d) said arrangement located at the top end or the bottom end of a cable;
whereby said arrangement causes deceleration of an object moving along said cable in a uniformly smooth and safe manner.

16. The spring compression braking system according to claim 15, further wherein optional compression stops are employed to control and limit the amount of compression of said springs for the purpose of not over-stressing said springs.

17. The spring compression braking system, according to claim 15, wherein the spring compression braking system is incorporated into a zip line amusement ride to control the acceleration and deceleration of the suspended zip line passenger chair connected to the free-wheeling cable.

18. A method for making a spring compression braking system, comprising the steps of:
a) providing one or more spring guides; and
b) providing one or more compression springs;
c) arranging of a series of one or more alternating spring guides and compression springs along a cable; and
d) locating said arrangement at the top end or the bottom end of a cable;
whereby said arrangement causes deceleration of an object moving along said cable in a uniformly smooth and safe manner.

19. The method of making a spring compression braking system, according to claim 18, further wherein optional compression stops are employed to control and limit the amount of compression of said springs for the purpose of not over-stressing said springs.

20. The speed control wheel mechanism, according to claim 18, wherein the spring compression braking system is incorporated into a zip line amusement ride to control the acceleration and deceleration of the suspended zip line passenger chair connected to the free-wheeling cable.
